(19) United States
(12) Patent Application Publication
(10) Pub. No.: US 2015/0255483 A1
(43) Pub. Date: Sep. 10, 2015

(54) INTEGRATED CIRCUIT DEVICE AND METHOD FOR MANUFACTURING THE SAME

(71) Applicant: Kabushiki Kaisha Toshiba, Minato-ku (JP)

(72) Inventor: Kotaro NODA, Yokkaichi (JP)

(73) Assignee: Kabushiki Kaisha Toshiba, Minato-ku (JP)

(21) Appl. No.: 14/482,535

(22) Filed: Sep. 10, 2014

(30) Foreign Application Priority Data
Mar. 7, 2014 (JP) 2014-044919

(51) Int. Cl. H01L 27/115

(52) U.S. Cl. CPC H01L 27/11582

(57) ABSTRACT

An integrated circuit device according to an embodiment includes a stacked structural body, a stopper film selectively provided in the stacked structural body, a first vertical member and a second vertical member provided in the stacked structural body. The first vertical member extends in a stacking direction of the stacked structural body and has a bottom end entering into the stopper film. The second vertical member extends in the stacking direction and passes a side of the stopper film. The stopper film has an upper film and a lower film. The upper film has a composition that differs from a composition of each portion of the stacked structural body. The lower film has a composition that differs from the composition of the upper film. The lower film has a maximum width less than the maximum width of the upper film.

### CROSS-REFERENCE TO RELATED APPLICATIONS

This application is based upon and claims the benefit of priority from Japanese Patent Application No.2014-044919, filed on Mar. 7, 2014; the entire contents of which are incorporated herein by reference.

### FIELD

Embodiments described herein relate generally to an integrated circuit device and a method for manufacturing the same.

### BACKGROUND

In recent years, a stacked-type memory device is proposed in which a memory cell is formed between a silicon pillar and an electrode film by forming a stacked body by alternately stacking insulating films and electrode films, forming a through-hole in the stacked body, forming a memory film that can accumulate a charge on an inner face of the through-hole, and forming a silicon pillar on an inner portion of the through-hole. Furthermore, in such a stacked-type memory device, the electrode film is divided into a plurality of portions by forming a slit in the stacked body, thereby increasing the controllability of each memory cell. However, this type of stacked-type memory device has a problem in that manufacturing is difficult when shrinking.

### BRIEF DESCRIPTION OF THE DRAWINGS

FIG. 1 is a cross sectional view illustrating an integrated circuit device according to a first embodiment;

FIGS. 2A to 10 are cross-sectional views illustrating a method for manufacturing the integrated circuit device according to the first embodiment;

FIGS. 11A to 11C are cross-sectional views illustrating a method for manufacturing an integrated circuit device according to a second embodiment; and

FIGS. 12A to 12C are cross-sectional views illustrating a method for manufacturing an integrated circuit device according to a variation of the second embodiment.

### DETAILED DESCRIPTION

An integrated circuit device according to an embodiment includes a stacked structural body, a stopper film selectively provided in the stacked structural body, a first vertical member provided in the stacked structural body and a second vertical member provided in the stacked structural body. The first vertical member extends in a stacking direction of the stacked structural body and has a bottom end entering into the stopper film. The second vertical member extends in the stacking direction of the stacked structural body and passes a side of the stopper film. The stopper film has an upper film and a lower film. The upper film has a composition that differs from a composition of each portion of the stacked structural body. The lower film has a composition that differs from the composition of the upper film. The lower film has a maximum width less than the maximum width of the upper film.

A method for manufacturing an integrated circuit according to an embodiment includes forming a structural body in which a lower structural body, a lower film, and an upper film having a composition differs from a composition of the lower film are stacked in this order. The method includes forming a stopper film by selectively removing the upper film and the lower film. The method includes performing side etching on the lower film. The method includes forming an upper structural body in which a composition of each portion differs from the composition of the upper film so as to cover the stopper film. The method includes forming a first hole that reaches the stopper film by etching the upper structural body. The method includes forming a first vertical member in the first hole. The method includes forming a second hole that passes a side of the stopper film by etching the upper structural body and the lower structural body. And, the method includes forming a second vertical member in the second hole.

### First Embodiment

Hereinafter, embodiments of the invention will be described below with reference to the drawings.

First, a first embodiment will be described.

An integrated circuit device according to the embodiment is a stacked-type non-volatile semiconductor memory device.

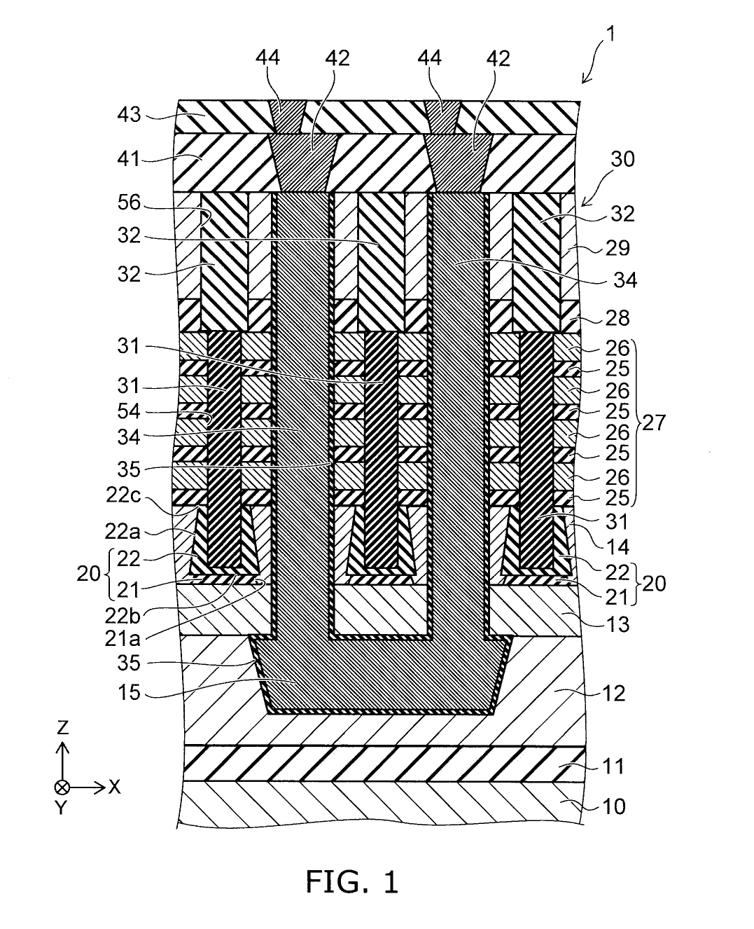

FIG. 1 is a cross sectional view illustrating an integrated circuit device according to the embodiment.

As illustrated in FIG. 1, in an integrated circuit device 1 according to the embodiment, a silicon substrate 10 is provided, and a silicon oxide film 11, and polysilicon films 12, 13, and 14 are stacked in this order on the silicon substrate 10. The polysilicon films 12, 13, and 14 are formed from polysilicon doped with boron (B), and a back gate electrode is formed from the polysilicon films 12, 13, and 14. A peripheral circuit may be formed between the silicon substrate 10 and the silicon oxide film 11. A pipe connector 15 formed from, for example, polysilicon is provided in an upper layer portion of the polysilicon film 12.

In this patent specification, the following XYZ orthogonal coordinate system is used for convenience of explanation. Two mutually perpendicular directions parallel to the upper face of the silicon substrate 10 are defined as the “X-direction” and the “Y-direction”, and a direction perpendicular to the upper face of the silicon substrate 10 is defined as the “Z-direction”. A shape of the pipe connector 15 is a substantially rectangular parallelepiped shape with the X-direction as the longitudinal direction.

A plurality of stopper films 20 is selectively provided in the polysilicon film 14. The plurality of stopper films 20 is disposed separated from each other in the X-direction and each of the stopper films 20 extends linearly along the Y-direction. A lower film 21 and an upper film 22 are provided on each of the stopper films 20, and the upper film 22 is disposed on the lower film 21.

In the upper film 22 of the stopper films 20, a side face 22a thereof is inclined in a sequential tapered shape, and the width of the upper film 22 is wider as it progresses downward. Because of this, the width of a lower end portion 22b of the upper film 22 is wider than the width of an upper end portion 22c of the upper film 22. Further, the upper film 22 is formed from, for example, metal, metal oxide, or metal nitride, or it is formed from one or more types of metal selected from the group consisting of, for example, titanium (Ti), aluminum (Al), tantalum (Ta), tungsten (W), molybdenum (Mo), manganese (Mn), and zirconium (Zr), or metal oxide or metal nitride thereof, and is formed from, for example, tantalum oxide (TaO).

The side face 21a of the lower film 21 is side-etched, and the maximum width of the lower film 21 is less than the maximum width of the upper film 22. Here, the “width” of the stopper film 20 is, for example, the length in the X-direction when, for example, the stopper film 20 is a linear member extending in the Y-direction. The “maximum width” is a maximum width recognized when observing one YZ cross-section that has one object, and, for example, the maximum width of the upper film 22 is often the width of the lower end portion 22b. Furthermore, a comparison of the maximum width of the lower film 21 and the maximum width of the upper film 22 is performed in one YZ cross-section of one stopper film 20, and can be determined by, for example, a scanning electron microscope (SEM) photograph.

Further, the composition of the lower film 21 differs from the composition of the upper film 22. The lower film 21 is formed from, for example, a metal or silicon, an oxide of these, or a nitride of these, it is formed from one or more types of material selected from the group consisting of, for example, silicon (Si), titanium (Ti), aluminum (Al), tantalum (Ta), tungsten (W), molybdenum (Mo), manganese (Mn) and zirconium (Zr), or an oxide thereof or a nitride thereof, and is formed from, for example, a silicon oxide (SiO₂).

A stacked body 27 with an inter-electrode insulating film 25 and a control gate electrode film 26 alternately stacked is provided on the polysilicon film 14. The inter-electrode insulating film 25 is formed from, for example, silicon oxide, and the control gate electrode film 26 is formed from, for example, polysilicon containing boron. In FIG. 1, an example is illustrated where the number of stacked layers of the inter-electrode insulating film 25 and the control gate electrode film 26 is four, respectively, but it is not limited to this. An inter-electrode insulating film 28 and a selection gate electrode film 29 are stacked in this order on the stacked body 27. The polysilicon layers 12, 13, and 14, the stacked body 27, the inter-electrode insulating film 28, and the selection gate electrode film 29 form a stacked structural body 30. The stacking direction of the stacked structural body 30 is the Z-direction. Furthermore, the composition of each portion of the stacked structural body 30 differs from the composition of the upper film 22.

A plate-shaped insulating member 31 extending in the Y-direction and the Z-direction is provided in the inner portion of the polysilicon film 14 and the stacked body 27. The bottom end of the insulating member 31 enters into the upper film 22 of the stopper film 20. A plate-shaped insulating member 32 extending in the Y-direction and the Z-direction is provided in the inner portion of the inter-electrode insulating film 28 and the selection gate electrode film 29. The insulating member 32 is disposed in a region directly above the insulating member 31 and contacts the insulating member 31. The insulating members 31 and 32 are formed from an insulating material such as silicon oxide. A first vertical member provided in the stacked structural body 30, extending in the stacking direction of the stacked structural body 30, and in which the bottom end enters into the stopper layer 20, is formed from the insulating members 31 and 32.

Further, a plurality of silicon pillars 34 extending in the Z-direction is provided so as to penetrate the polysilicon films 13 and 14, the stacked body 27, the inter-electrode insulating film 28, and the selection gate electrode film 29. The shape of the silicon pillars 34 is a substantially circular columnar shape thinner as it progresses downward. The silicon pillars 34 pass between the stopper films 20 without contacting the stopper films 20, and the bottom ends thereof contact both ends in the X-direction of the pipe connector 15. The silicon pillars 34 are provided in the stacked structural body 30, extend in the stacking direction of the stacked structural body 30, and are a second vertical member that passes a side of the stopper films 20.

A structural body formed from one pipe connector 15 and two silicon pillars 34 connected thereto is integrally formed from polysilicon, and a memory film 35 is provided on the surface of the structural body. The memory film 35 is a film that exchanges a charge with the silicon pillars 34 and can accumulate a charge.

For example, in the memory film 35, a tunnel insulating layer, a charge storage layer, and a block insulating layer are stacked in this order from the side of the pipe connector 15 and the silicon pillar 34. The tunnel insulating layer is a layer that is normally insulating, but when a predetermined voltage that is within the drive voltage range of the integrated circuit device 1 is applied, a tunnel current flows. The charge storage layer is a layer that has the capability of accumulating charge, for example, a layer that includes electron trap sites. The block insulating layer is a layer through which a current does not substantially flow even when a voltage that is within the driving voltage range of the integrated circuit device 1 is applied. For example, the tunnel insulating layer and the block insulating layer are formed from silicon oxide, and the charge storage layer is formed from silicon nitride.

An interlayer insulating film 41 is provided on the stacked structural body 30, and a plug 42 connected to the silicon pillar 34 is provided in the interlayer insulating film 41. An interlayer insulating film 43 is provided on the interlayer insulating film 41, and a plug 44 connected to the plug 42 is provided in the interlayer insulating film 43.

Next, a method for manufacturing the integrated circuit device according to the embodiment will be described.

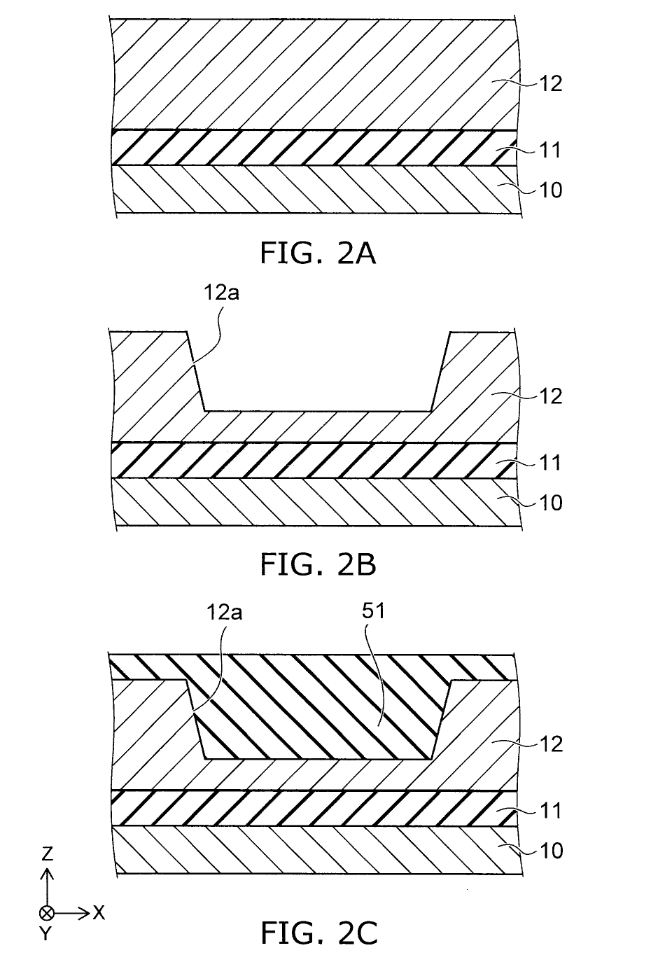

FIGS. 2A to 10 are cross-sectional views illustrating a method for manufacturing the integrated circuit device according to the embodiment.

First, as illustrated in FIG. 2A, the silicon oxide film 11 is formed on the silicon substrate 10, and the polysilicon film 12 is formed on the silicon oxide film 11. A peripheral circuit may be formed between the silicon substrate 10 and the silicon oxide film 11.

Next, as illustrated in FIG. 2B, a concave portion 12a with the X-direction as the longitudinal direction is formed on the upper face of the polysilicon film 12.

Next, as illustrated in FIG. 2C, a sacrificial material 51, for example, silicon nitride is deposited on the polysilicon film 12. The sacrificial material 51 is also embedded within the concave portion 12a.

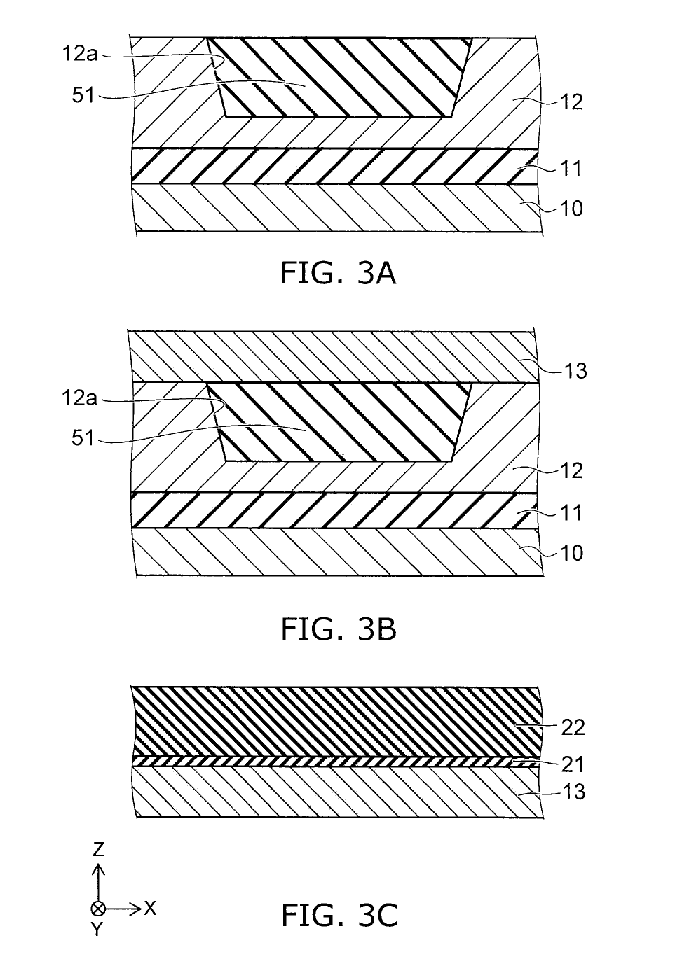

Next, as illustrated in FIG. 3, a chemical mechanical polishing (CMP) is performed on the upper face of the sacrificial material 51, and portions of the sacrificial material 51 deposited on the outer side of the concave portion 12a are removed.

Next, as illustrated in FIG. 3B, the polysilicon film 13 is formed above the polysilicon film 12 and the sacrificial material 51 as a lower structural body.

Next, as illustrated in FIG. 3C, the lower film 21 is formed on the polysilicon film 13. The lower film 21 is formed from, for example, a metal or silicon, an oxide thereof or a nitride thereof, and is formed from, for example, a silicon oxide (SiO₂). The lower film 21 may also be formed from silicon (Si) or silicon nitride (SiN).

Next, the upper film 22 is formed. The composition of the upper film 22 is made to differ from the composition of the lower film 21. The upper film 22 is formed from, for example, metal, metal oxide, or metal nitride, and is formed from, for example, tantalum oxide (TaO). The lower film 21 and the upper film 22 are formed by, for example, a low pressure chemical vapor deposition (LP-CVD) method, a plasma enhanced CVD (PE-CVD) method, a physical vapor deposition (PVD) method, or an atomic layer deposition (ALD) method. In FIGS. 3C to 7, illustrations of the structure lower than the polysilicon film 13 are omitted for simplification.

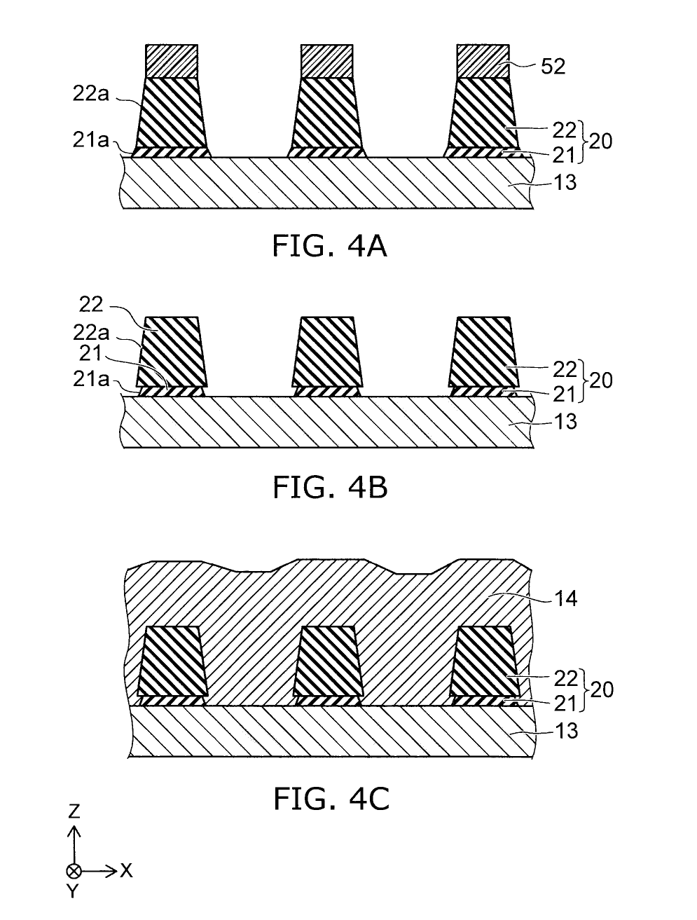

Next, as illustrated in FIG. 4A, a linear resist mask 52 extending in the Y-direction is formed on the upper film 22 by a lithography method. Next, an anisotropic etching such as reactive ion etching (RIE) is performed with the resist mask 52 as the mask. Through this, the upper film 22 and the lower film 21 are selectively removed and are processed in a line-and-space form extending in the Y-direction. At this time, the side face 22a of the upper film 22 and the side face 21a of the lower film 21 are inclined in a sequential tapered shape. Therefore, the maximum width of the lower film 21 is greater than the maximum width of the upper film 22, and the width becomes greater as it progresses downward on each of the upper film 22 and the lower film 21. The stopper films 20 are formed by the processed lower film 21 and the upper film 22.

Next, as illustrated in FIG. 4B, side etching is performed on the lower film 21. This etching is performed under condition so that the etching rate of the lower film 21 is higher than the etching rate of the upper film 22. For example, when the lower film 21 is formed from silicon oxide, wet etching is performed using diluted hydrofluoric acid (DHF) as the etching solution. When the lower film 21 is formed from silicon, wet etching is performed using hot phosphoric acid as the etching solution. When the lower film 21 is formed from silicon nitride, wet etching is performed using a choline aqueous solution (TMY) as the etching solution. Alternatively, in place of these wet etchings, dry etching may be performed such as RIE using CF gas as the etching gas. Through this side etching, the side face 21a of the lower film 21 recedes more than the side face 22a of the upper film 22, and the maximum width of the lower film 21 becomes smaller than the maximum width of the upper film 22.

Next, as illustrated in FIG. 4C, polysilicon doped with boron (B) is deposited on the entire face so as to cover the stopper film 20, and thereby forming the polysilicon film 14.

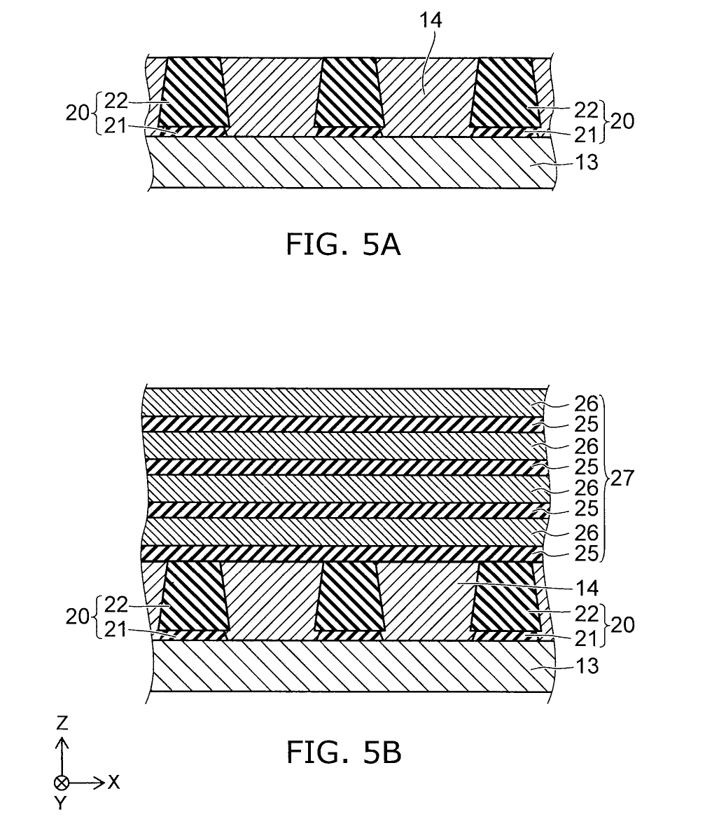

Next, as illustrated in FIG. 5A, the upper face of the polysilicon film 14 is flattened to expose the upper face of the upper film 22.

Next, as illustrated in FIG. 5B, the inter-electrode insulating film 25 formed from, for example, silicon oxide, and the control gate electrode film 26 formed from, for example, polysilicon doped with boron, are alternately stacked to form the stacked body 27 as an upper structural body.

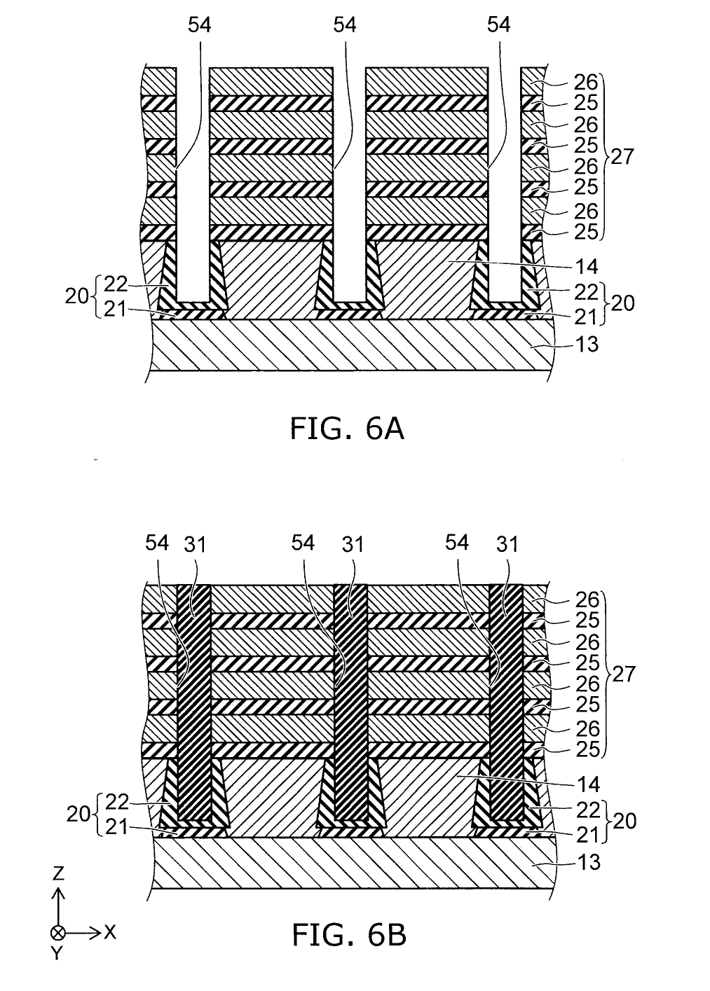

Next, as Illustrated in FIG. 6A, a slit 54 expanding in the Y-direction and the Z-direction is formed in a region directly above the stopper film 20 by selectively removing the stacked body 27 using lithography and dry etching. At this time, because etching is stopped in the stopper film 20, the bottom end of the slit 54 enters into the upper film 22 of the stopper film 20 but does not pierce through the upper film 22.

Next, as illustrated in FIG. 6B, by depositing an insulating material on the entire face and flattening the upper face, the insulating member 31 is embedded within the slit 54.

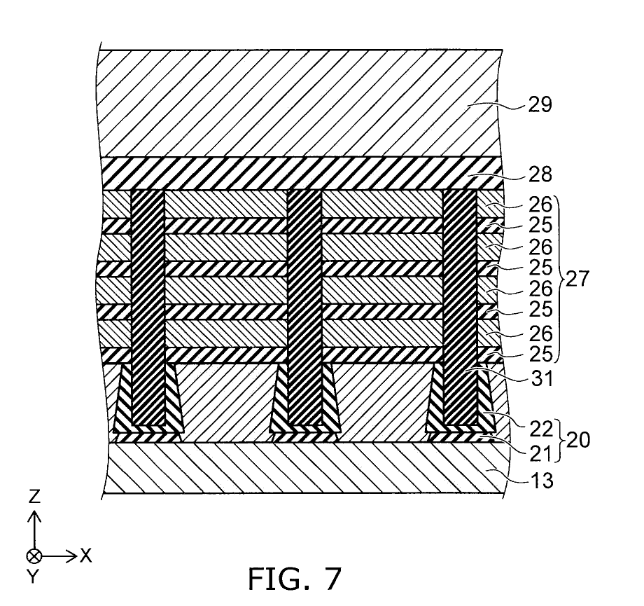

Next, as illustrated in FIG. 7, an inter-electrode insulating film 28 formed from, for example, silicon oxide, and a selection gate electrode film 29 formed from, for example, polysilicon, are formed. In this manner, each composition of the inter-electrode insulating film 25 that covers the stopper film 20, the selection gate electrode film 26, the inter-electrode insulating film 28, and the selection gate electrode film 29 is made to differ from the composition of the upper film 22.

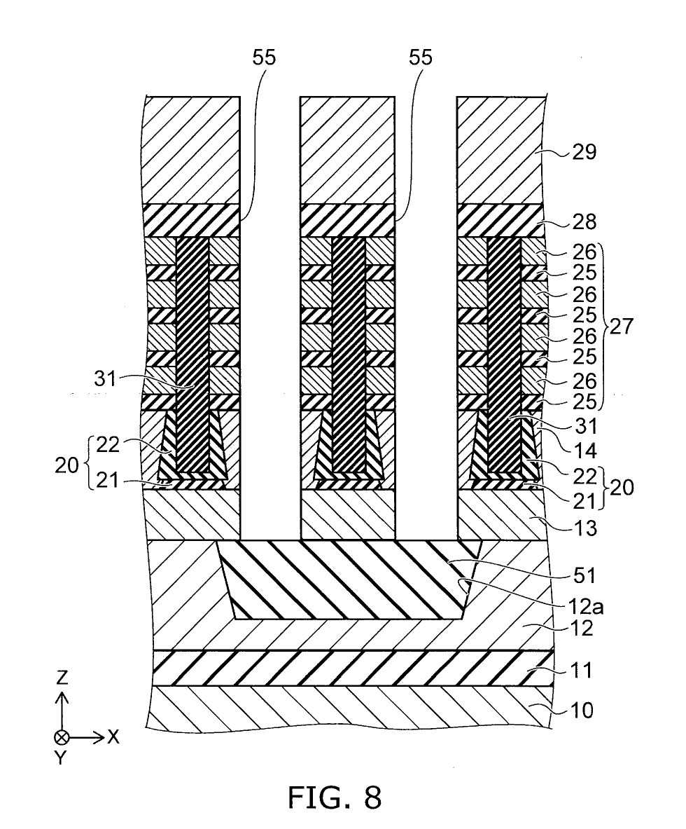

Next, as illustrated in FIG. 8, a memory hole 55 extending in the Z-direction is formed by lithography and etching, to pass a region between the stopper films 20 and pass through the selection gate electrode film 29, the inter-electrode insulating film 28, the stacked body 27, and the polysilicon films 14 and 13 to reach both end portions in the X-direction of the concave portion 12a of the polysilicon film 12, and then is communicated to the concave portion 12a. At this time, the memory hole 55 is formed to pass by the side of the stopper films 20 so as not to contact the stopper films 20.

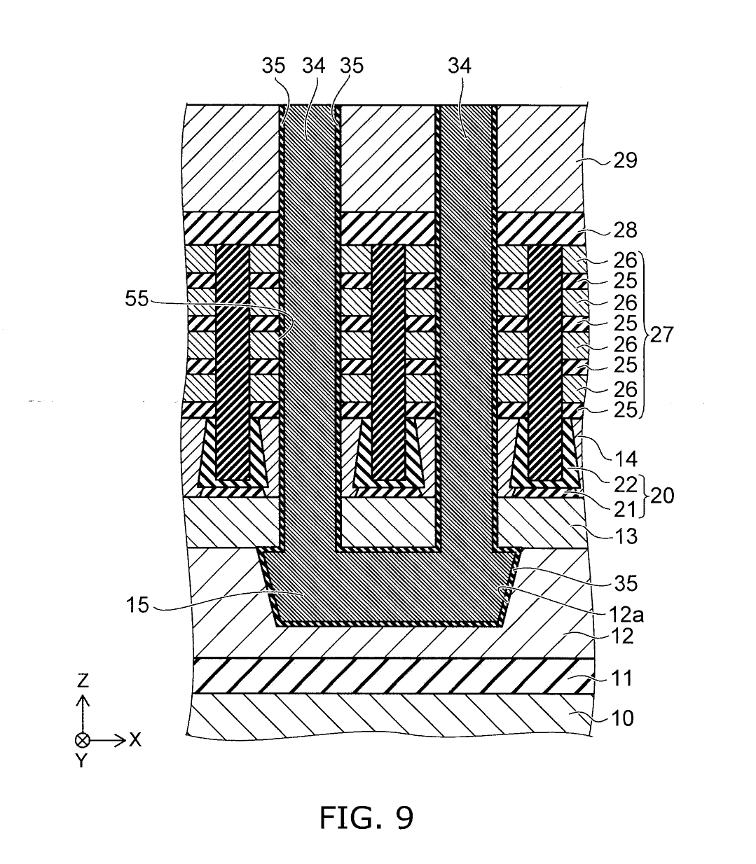

Next, as illustrated in FIG. 9, wet etching is performed via the memory hole 55, and the sacrificial material 51 is removed from the concave portion 12a. Next, a block insulating layer, a charge storage layer, and a tunnel insulating layer are formed in this order on an inner face of a cavity formed by the concave portion 12a and the memory hole 55, and a memory film 35 is formed. Next, polysilicon is embedded within the cavity formed by the concave portion 12a and the memory hole 55. Through this, the pipe connector 15 is formed in the concave portion 12a, and the silicon pillars 34 are formed in the memory hole 55.

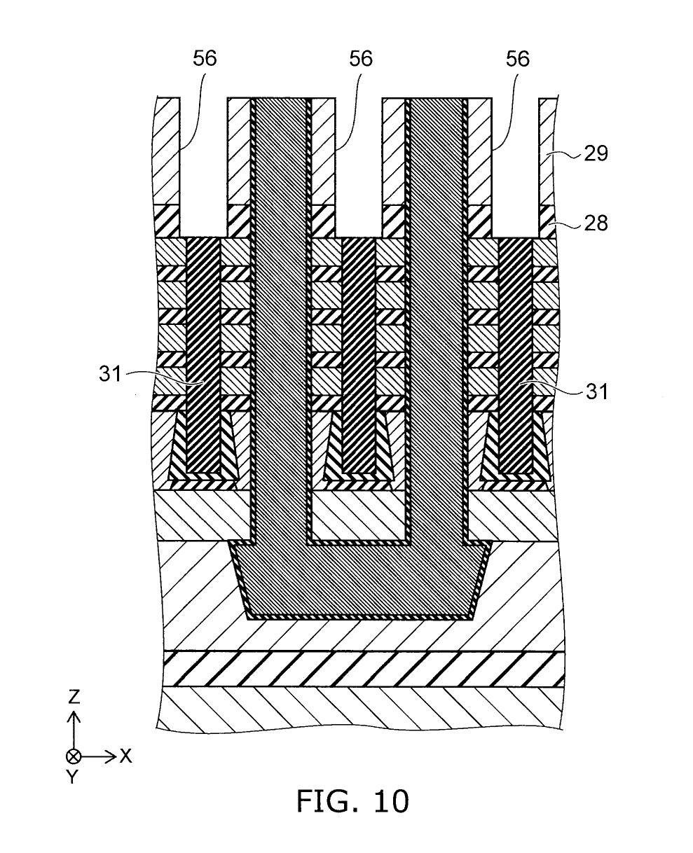

Next, as illustrated in FIG. 10, the selection gate electrode film 29 and the inter-electrode insulating film 28 are selectively removed, and a slit 56 is formed in the region directly above the insulating member 31 by lithography and etching.

Next, as illustrated in FIG. 1, the insulating member 32 is embedded within the slit 56 by depositing an insulating material such as, for example, silicon oxide, and performing a flattening process.

Next, the interlayer insulating film 41 is formed, a hole is formed in the interlayer insulating film 41, and a plug 42 is formed in the interlayer insulating film 41 by depositing metal material and performing CMP. Next, the interlayer insulating film 43 is formed, a hole is formed in the interlayer insulating film 43, and a plug 44 is formed in the interlayer insulating film 43 by depositing metal material and performing CMP. In this way, the integrated circuit device 1 according to the embodiment is manufactured.

Next, effects of the embodiment will be described.

In the process illustrated in FIG. 4A, when forming the stopper films 20 by etching, the side face of the stopper films 20 is inevitably inclined in a sequential tapered shape because of the nature of the etching, and the width of the lower portion of the stopper film 20 becomes greater than the width of the upper portion.

Therefore, in the embodiment, in the process illustrated in FIG. 4B, the maximum width of the lower film 21 is made less than the maximum width of the upper film 22 by performing side etching on the lower film 21 of the stopper film 20. Through this, in the process illustrated in FIG. 8, it becomes harder for the memory hole 55 to contact the stopper film 20 when forming the memory hole 55. If the memory hole 55 does not contact the stopper film 20, the etching for forming the memory hole 55 will not be prevented by the stopper film 20, and portions positioned lower than the stopper film 20 in the memory hole 55 will not be thinner. Therefore, the memory film 35 and the silicon pillars 34 can be surely formed.

Furthermore, in the embodiment, in the process illustrated in FIG. 4B, the upper film 22 is not substantially etched when performing side etching on the lower film 21 of the stopper films 20 by taking a high etching selectivity with respect to the upper film 22. Through this, the upper film 22 is prevented from becoming too thin, and in the process illustrated in FIG. 6A, it is possible to prevent the slit 54 from slipping through the side of the stopper films 20 when forming the slit 54, and reaching lower than the stopper films 20. As a result, the back gate electrode formed from the polysilicon films 12 to 14 is prevented from being divided by the slit 54.

In this manner, according to the embodiment, forming the lower film 21 of the stopper film 20 with a different material than the upper film 22 and performing side etching on only the lower film 21, allows the stopper film 20 to be prevented from being interposed between the memory holes 55, and allows the etching for forming the slit 54 to be surely stopped by the stopper film 20. As a result, the integrated circuit device according to the embodiment is simple to manufacture even when shrinking.

Meanwhile, if the lower film 21 is not side etched for example, a gap between the stopper films 20 becomes narrower, and it becomes difficult to form a memory hole 55 that can pass through this gap. If the memory hole 55 contacts the stopper films 20, subsequent etching is prevented, and portions lower than the stopper films 20 in the memory hole 55 become thinner. As a result, in the process illustrated in FIG. 9, there is a possibility of film clogging occurring when forming the memory film 35, the silicon pillars 34, and the like, and the shape may not be formed as designed. Meanwhile, if the width of the stopper film 20 is lessened to prevent this, in the process illustrated in FIG. 6B, the slit 54 slips through the side of the stopper films 20 when forming the slit 54, and there is a possibility that the lower structure will be damaged. As the integrated circuit device is shrunk, because the margin for forming the memory hole 55 and the slit 54 becomes small, the above risks increase, and manufacturing of the integrated circuit device becomes difficult.

At least one of the lower film 21 and the upper film 22 may be formed by a conductive material such as metal. By this, resistance of the back gate electrode formed from the polysilicon films 12 to 14 can be reduced.

Also, the process for forming the slit 54 illustrated in FIG. 6A and the process for forming the memory hole 55 illustrated in FIG. 8 may be done in the opposite order.

### Second Embodiment

Next a second embodiment will be described.

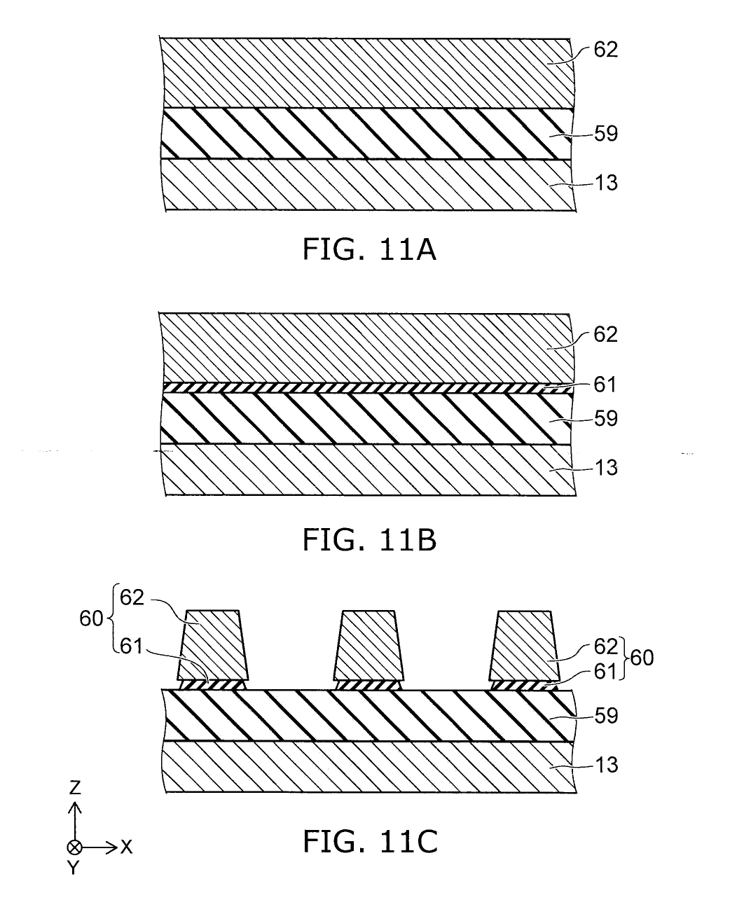

FIGS. 11A to 11C are cross-sectional views illustrating a method for manufacturing an integrated circuit device according to the embodiment.

First, the processes illustrated in FIGS. 2A to 3B are performed, and the silicon oxide film 11, and the polysilicon films 12 and 13 are formed on the silicon substrate 10.

Next, as illustrated in FIG. 11A, a foundation film 59 is formed on the polysilicon film 13. The foundation film 59 is formed from a material containing oxygen, for example, silicon oxide. Next, an upper film 62 is formed. The upper film 62 is formed from, for example, metal, and is formed from one or more types of metal selected from the group consisting of, for example, titanium (Ti), aluminum (Al), tantalum (Ta), tungsten (W), molybdenum (Mo), manganese (Mn) and zirconium (Zr).

Next, as illustrated in FIG. 11B, performing an annealing causes the foundation film 59 and the upper film 62 to react, and a reaction layer 62 is formed between the foundation film 59 and the upper film 62. Specifically, the metal contained in the upper film 62 is oxidized by the oxygen contained in the foundation film 59, and the reaction layer 61 formed from the oxide of the metal is formed.

Next, as illustrated in FIG. 11C, the upper film 62 and the reaction layer 61 are processed into a line-and-space form extending in the Y-direction by an etching using a resist mask. Stopper films 60 are formed by the processed upper film 62 and the reaction layer 61. At this time, the reaction layer 61 becomes a lower film.

Next, side etching is performed on the reaction layer 61. This side etching is performed under the condition so that the etching rate of the reaction layer 61 is higher than the etching rate of the upper film 62, and the side etching is performed by, for example, wet etching. Through this, a side face of the reaction layer 61 recedes, and the maximum width of the reaction layer 61 becomes less than the maximum width of the upper film 62. Next, the processes illustrated in FIGS. 4C to 11 are carried out.

Even in the embodiment, in the process illustrated in FIG. 11C, the maximum width of the reaction layer 61 can be made smaller than the maximum width of the upper film 62 by performing side etching on only the reaction layer 61, and the same effects can be achieved as with the first embodiment described above. The configuration, manufacturing method and effect of the embodiment other than that described above is the same as the first embodiment as described previously.

### Variation of the Second Embodiment

Next, a variation of the second embodiment will be described.

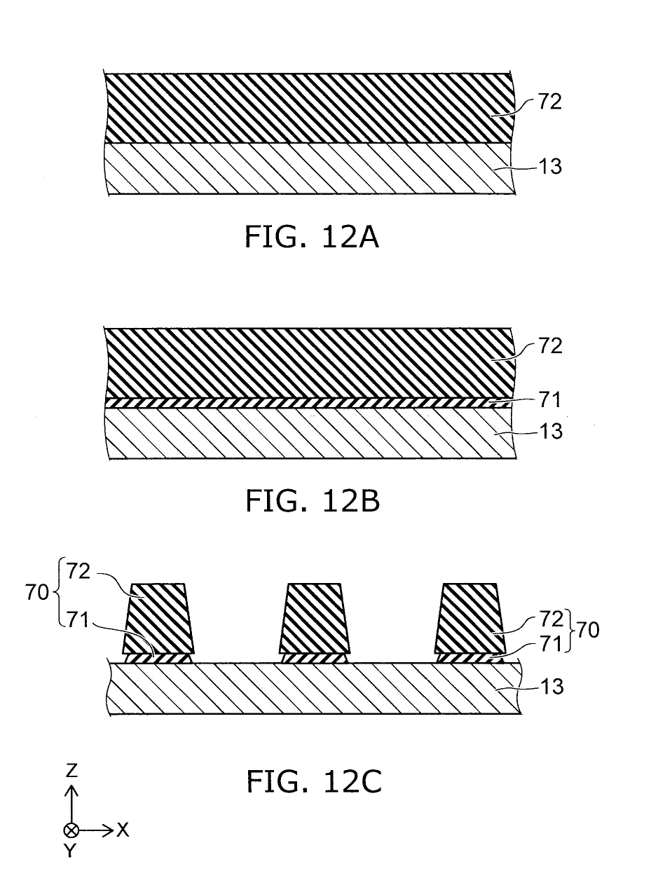

FIGS. 12A to 12C are cross-sectional views illustrating a method for manufacturing an integrated circuit device according to the variation.

The variation differs compared to the second embodiment described above in the fact that the polysilicon film 13 is used as a foundation film.

First, the processes illustrated in FIGS. 2A to 3B are performed, and the silicon oxide film 11, and the polysilicon films 12 and 13 are formed on the silicon substrate 10.

Next, as illustrated in FIG. 12A, an upper film 72 is formed on the polysilicon film 13. The upper film 72 is formed from metal.

Next, an annealing is performed as illustrated in FIG. 12B. By this, the polysilicon film 13 and the upper film 72 react, and a reaction layer 71 formed from silicide of the metal that forms the upper film 72 is formed between the polysilicon film 13 and the upper film 72.

Next, as illustrated in FIG. 12C, the upper film 72 and the reaction film 71 are processed into a line-and-space form extending in the Y-direction, and stopper films 70 are formed. Next, the maximum width of the reaction layer 71 is made smaller than the maximum width of the upper film 72 by performing side etching on the reaction layer 71. The configuration, manufacturing method, and effect of this variation other than that described above is the same as the second embodiment as described previously.

Note that in the second embodiment described above, an example was described where a reaction layer is formed by oxidizing a metal contained in an upper film, and in the variation of the second embodiment, an example was described where the reaction layer is formed by siliciding the metal contained in the upper film, but the invention is not limited to these, and it is sufficient that a film be formed so as to realize etching selectivity as a lower film with respect to the upper film. For example, a reaction layer formed from metal nitride may be formed by containing nitrogen in the foundation film, containing metal in the upper film, and nitriding the metal.

According to the embodiments described above, an integrated circuit device that is simple to manufacture even when shrinking and a method for manufacturing the same can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An integrated circuit device, comprising:
a stacked structural body;
a stopper film selectively provided in the stacked structural body;
a first vertical member provided in the stacked structural body, extending in a stacking direction of the stacked structural body, having a bottom end entering into the stopper film; and
a second vertical member provided in the stacked structural body, extending in the stacking direction of the stacked structural body, and passing a side of the stopper film,
the stopper film including:
an upper film having a composition that differs from a composition of each portion of the stacked structural body; and
a lower film having a composition that differs from the composition of the upper film and having a maximum width less than the maximum width of the upper film.

2. The device according to claim 1, wherein the upper film has a larger width as it progresses downward.

3. The device according to claim 1, wherein the upper film is formed from one or more types of metal selected from the group consisting of titanium, aluminum, tantalum, tungsten, molybdenum, manganese, and zirconium, or an oxide thereof or a nitride thereof.

4. The device according to claim 1, wherein the lower film is formed from one or more types of material selected from the group consisting of silicon, titanium, aluminum, tantalum, tungsten, molybdenum, manganese, and zirconium, or an oxide thereof or a nitride thereof.

5. The device according to claim 1, wherein the lower film is formed from an oxide of a metal, the metal is contained in the upper film.

6. The device according to claim 1, wherein the lower film is formed from a silicide of a metal, the metal is contained in the upper film.

7. The device according to claim 1, wherein a shape of the stopper film is a linear shape extending in a first direction perpendicular to the stacking direction,
a shape of the first vertical member is a plate shape expanding in the stacking direction and the first direction, and
a shape of the second vertical member is a columnar shape.

8. The device according to claim 1, further comprising a memory film provided on a side face of the second vertical member, wherein
the stacked structural body includes a plurality of electrode films and insulating films each alternately stacked,
the first vertical member is formed from an insulating material, and
the second vertical member is formed from a semiconductor material.

9. A method for manufacturing an integrated circuit, comprising:
forming a structural body in which a lower structural body, a lower film, and an upper film having a composition differs from a composition of the lower film are stacked in this order;
forming a stopper film by selectively removing the upper film and the lower film;
performing side etching on the lower film;
forming an upper structural body in which a composition of each portion differs from the composition of the upper film so as to cover the stopper film;
forming a first hole that reaches the stopper film by etching the upper structural body;
forming a first vertical member in the first hole;
forming a second hole that passes a side of the stopper film by etching the upper structural body and the lower structural body; and
forming a second vertical member in the second hole.

10. The method according to claim 9, wherein the forming the structural body includes:
forming the lower film on the lower structural body; and
forming the upper film on the lower film.

11. The method according to claim 9, wherein the forming the structural body includes:
forming the upper film on the lower structural body; and
forming the lower film between the lower structural body and the upper film by causing the lower structural body and the upper film to react.

12. The method according to claim 11, wherein oxygen is contained in the lower structural body, metal is contained in the upper film, and the reaction is an oxidation reaction of the metal.

13. The method according to claim 11, wherein silicon is contained in the lower structural body, metal is contained in the upper film, and the reaction is a silicidation reaction of the metal.

14. The method according to claim 9, wherein the forming the structural body includes forming the upper film by a low pressure chemical vapor deposition method, a plasma enhanced chemical vapor deposition method, a physical vapor deposition method, or an atomic layer deposition method.

15. The method according to claim 9, wherein the performing side etching on the lower film includes performing wet etching on the stopper film under the condition so that the etching rate of the lower film is higher than the etching rate of the upper film.

16. The method according to claim 9, wherein the performing side etching on the lower film includes performing dry etching on the stopper film under the condition so that the etching rate of the lower film is higher than the etching rate of the upper film.

17. The method according to claim 9, further comprising forming a memory film on the inner face of the second hole, wherein
the forming the upper structure includes alternately stacking electrode films and insulating films,
the first vertical member is formed of an insulating material, and
the second vertical member is formed of a semiconductor material.
